(19) United States
(12) Patent Application Publication
(10) Pub. No.: US 2007/0030094 A1
(43) Pub. Date: Feb. 8, 2007

(54) Duplexer and communication apparatus

(76) Inventor: Ryoichi Omote, Shiga-ken (JP)

Correspondence Address: MURATA MANUFACTURING COMPANY, LTD.;C/O KEATING & BENNETT, LLP, 8180 GREENSBORO DRIVE, SUITE 850, MCLEAN, VA, 22102, US

(21) Appl. No.: 10/595,235

(22) PCT Filed: Aug. 8, 2005
(86) PCT No.: PCT/JP05/14500

§ 371 Date: Mar. 28, 2006

(30) Foreign Application Priority Data
Aug. 11, 2004 (JP) 2004-234547

(51) Int. Cl. H03H 9/72

(52) U.S. Cl. 333/133; 333/193

(57) ABSTRACT

A duplexer includes transmission-side and reception-side band filters respectively including a plurality of surface acoustic wave resonators connected together to define a ladder circuit. Each of the surface acoustic wave resonators includes a 47° to 58° rotated, Y-cut, X-propagating LiNbO₃ substrate and an IDT electrode provided on the LiNbO₃ substrate. The IDT electrode includes a Ti foundation electrode layer provided on the LiNbO₃ substrate formed through epitaxial growth and an Al electrode layer formed through epitaxial growth on the Ti foundation electrode layer, and a (111) face of the Al electrode layer, a (001) face or (100) face of the Ti foundation electrode layer, and a (001) face of the LiNbO₃ substrate are aligned in parallel.

### BACKGROUND OF THE INVENTION

1. Field of the Invention

The present invention relates to a duplexer and a communication device used in communications equipment, and more particularly, to a duplexer and a communication device that are provided with a band filter including a plurality of surface acoustic wave resonators that define a ladder circuit.

2. Description of the Related Art

In general, in a surface acoustic wave element, an interdigital electrode (IDT electrode) having a plurality of electrode fingers is provided on a piezoelectric substrate. The electrode fingers of the IDT electrode are narrow, and the pitch between the electrode fingers is extremely small. Therefore, when a large electric power is applied, short circuiting may occur between the electrode fingers and breaking may occur in the electrode fingers. Accordingly, improvement in the electric power resistance is highly desired for the surface acoustic wave element.

Japanese Unexamined Patent Application Publication No. 2002-353768 (Patent Document 1) described below discloses a surface acoustic wave element having increased electric power resistance. On a 64° Y-X-cut LiNbO₃ substrate, an IDT electrode is formed by laminating a Ti foundation electrode layer formed through epitaxial growth and an Al electrode layer formed further through epitaxial growth on the Ti foundation electrode layer. The (111) face of the crystal of the Al electrode layer, the (001) face or (100) face of the crystal of the Ti foundation electrode layer, and the (001) face of an LiTaO₃ substrate are aligned in parallel, whereby the electric power resistance is increased.

On the other hand, in a duplexer used for a mobile phone based on the W-CDMA system, a plurality of surface acoustic wave elements are connected to define a reception-side band filter and a transmission-side band filter. FIG. 20 shows an example of such a related-art duplexer circuit. In FIG. 20, an area surrounded by a dashed line defines a duplexer 201. The duplexer 201 includes an antenna terminal 201a. The antenna terminal 201a is connected to an antenna 202. Furthermore, an external inductance 203 and an external capacitor 204 are connected between the antenna terminal 201a and the antenna 202. Specifically, the inductance 203 is inserted between the antenna terminal 201a and the antenna 202 and the capacitor 204 is connected between a connection point between the antenna 202 and the inductance 203 and a ground potential.

The duplexer 201 includes a transmission-side band filter 201A and a reception-side band filter 201B. In the transmission-side band filter 201A, a plurality of serial arm resonators Sa to Sc and parallel arm resonators Pa and Pb are connected to define a ladder circuit. An inductance element 205 is connected in parallel with respect to the serial arm resonator Sc in the last pole. Also, in the reception-side band filter 201B, a plurality of serial arm resonators Sd to Sf are connected to a plurality of parallel arm resonators Pc and Pd to define a ladder circuit. An inductance element 206 is connected in parallel with respect to the serial arm resonator Se in the center.

Furthermore, inductance elements 207 and 208 are connected between the parallel arm resonators Pa and Pb of the transmission-side band filter and the ground potential.

With the surface acoustic wave element having the electrode construction described in Patent Document 1, the electric power resistance can be increased as described above. However, when the surface acoustic wave elements described in Patent Document 1 are used for the serial arm resonators Sa to Sc, the parallel arm resonators Pa and Pb, the serial arm resonators Sd to Sf, and the parallel arm resonators Pc and Pd of the duplexer 201 shown in FIG. 20, the electric power resistance is increased, but an out-of-band attenuation is not sufficient and an isolation characteristic is not satisfactory. This will be described with reference to FIGS. 21 to 23.

The surface acoustic wave elements having the electrode construction described in Patent Document 1 are used for the serial arm resonators Sa to Sc and Sd to Sf, and the parallel arm resonators Pa to Pd, and a 64° rotated, Y-cut LiNbO₃ substrate is used in the duplexer 201. FIG. 21 shows a frequency characteristic of the transmission-side band filter 201A, and FIG. 22 shows a frequency characteristic of the reception-side band filter 201B. It should be noted that curved lines on the lower side of FIGS. 21 and 22 represent the frequency characteristics in pass bands shown through magnification of the corresponding frequency characteristics. Then, FIG. 23 shows an isolation characteristic of the duplexer 201.

In the duplexer of the mobile phone based on the W-CDMA method, the attenuation in the outer vicinity of the pass band on the high pass side of 1920 MHz to 1980 MHz, namely, in the pass band of the reception-side band filter, is required to be at least about 40 dB. In view of the above, in the transmission-side band filter 201A shown in FIG. 20, by connecting the inductance 205 to the serial arm resonator Sc, an insertion loss is sacrificed to provide an attenuation pole on the outer side of the high pass in the bass band, thereby achieving the increase in the attenuation. However, as is apparent from FIG. 21, even when the above-mentioned attenuation pole is provided, the attenuation on the outer side of the high pass in the bass band is merely about 40 dB.

Furthermore, as shown in FIG. 23, the isolation characteristic in 2110 MHz to 2170 MHz corresponding to the reception-side pass band is merely about 40 dB as well. On the other hand, the characteristics of the duplexer 201 vary depending on the temperature. Therefore, the attenuation in the reception-side pass band cannot be reliably maintained to be equal to or greater than 40 dB over the temperature range in which the duplexer 201 is used.

### SUMMARY OF THE INVENTION

To overcome the problems described above, preferred embodiments of the present invention provide a duplexer including a plurality of surface acoustic wave elements in which not only the electric power resistance can be increased but also the out-of-band attenuation and the isolation characteristic can be set to a satisfactorily large value, and also relates to a communication device including the duplexer.

A duplexer according to a preferred embodiment of the present invention includes a transmission-side band filter and a reception-side band filter respectively including a plurality of surface acoustic wave resonators connected together to define a ladder circuit. Each of the surface acoustic wave resonators includes a 47° to 58° rotated, Y-cut, X-propagating LiNbO₃ substrate and an IDT electrode provided on the LiNbO₃ substrate. The IDT electrode includes a Ti foundation electrode layer provided on the LiNbO₃ substrate and an Al electrode layer provided on the Ti foundation electrode layer. A (111) face of the Al electrode layer, a (001) face or (100) face of the Ti foundation electrode layer, and a (001) face of the LiNbO₃ substrate are aligned in parallel.

Preferably, the Ti foundation electrode layer is formed through epitaxial growth on the LiNbO₃ substrate and the Al electrode layer is formed through epitaxial growth on the Ti foundation electrode layer.

In the reception-side band filter, a first inductance is disposed in parallel with respect to at least one serial arm resonator connected to a serial arm of the ladder circuit among the plurality of surface acoustic wave resonators, and in the transmission-side band filter, a second inductance is disposed between a parallel arm resonator connected to a parallel arm of the ladder circuit among the plurality of surface acoustic wave resonators and a ground potential. The first inductance and the second inductance are respectively defined by at least one of a wire bonding used for electrical connection in the duplexer, a line embedded in the duplexer, and an external coil component.

A communication device according to another preferred embodiment of the present invention includes the duplexer as described above, in which the duplexer includes an antennal terminal, a third inductance is inserted between the antennal terminal and the antenna, and the duplexer further includes a capacitor connected between a connection point between the third inductance and the antennal and the ground potential.

In the duplexer according to preferred embodiments of the present invention, the transmission-side band filter includes a plurality of surface acoustic wave resonators which are connected to define a ladder circuit and the reception-side band filter includes a plurality of surface acoustic wave resonators which are connected to define a ladder circuit. Then, each of the surface acoustic wave resonators includes the Ti foundation electrode layer provided on the LiNbO₃ substrate and the Al electrode layer provided on the Ti foundation electrode layer, and the (111) face of the Al electrode layer, the (001) face or (100) face of the Ti foundation electrode layer, and the (001) face of the LiNbO₃ substrate are aligned in parallel. Thus, each of the surface acoustic wave resonators has a sufficient electric power resistance. Therefore, the electric power resistance of the duplexer is increased.

Moreover, the 47° to 58° rotated, Y-cut, X-propagating LiNbO₃ substrate is used, and as is apparent from experiments to be described later, not only the electric power resistance is increased, but also, the attenuation on the high pass side of the pass band is set to have a sufficiently large value. At the same time, it is possible to effectively improve the isolation characteristic.

As a result, according to preferred embodiments of the present invention, for example, it is possible to provide the duplexer which is suitably used as the duplexer in the mobile phone based on the W-CDMA method, which is superior in the electric power resistance, and which has large attenuation and isolation characteristics.

Preferably, the Ti foundation electrode layer and the Al electrode layer are formed through epitaxial growth, and the (111) face of the Al electrode layer and the (001) face or (100) face Ti foundation electrode layer are aligned in parallel with respect to the (001) face of LiNbO₃ substrate.

In the reception-side band filter, as the first inductance is inserted in parallel with respect to at least one serial arm resonator connected to the serial arm among the plurality of surface acoustic wave resonators connected in a ladder configuration, when the second inductance is inserted between the parallel arm resonator connected to the parallel arm of the ladder circuit and the ground potential, the out-of-band attenuation can be set to an even larger value.

When the first inductance inserted in parallel with respect to the serial arm resonator of the reception-side band filter and the second inductance between the parallel arm resonator of the transmission-side band filter and the ground potential are respectively defined by at least one of the wire bonding wire bonding used for electrical connection in the duplexer, the line embedded in the duplexer, and the external coil part, it is possible to construct the first and second inductances without providing external components or other additional components. Therefore, the duplexer according to preferred embodiments of the present invention does not increase the number of components required for the duplexer.

The communication device according to another preferred embodiment of the present invention includes the duplexer according to various preferred embodiments of the present invention, the third inductance is inserted between the antenna terminal and the antenna, and the capacitor is connected between a connection point between the third inductance and the antenna and the ground potential. Therefore, the attenuation outside the pass band and the isolation characteristic are effectively improved.

Other features, elements, steps, characteristics and advantages of the present invention will become more apparent from the following detailed description of preferred embodiments of the present invention with reference to the attached drawings.

### BRIEF DESCRIPTION OF THE DRAWINGS

FIG. 1(a) is a circuit diagram of a circuit configuration of a duplexer according to a first preferred embodiment of the present invention, and FIG. 1(b) is a partially notched frontal cross-sectional view showing a construction of an IDT electrode.

FIG. 2 is a schematic plan view showing a specific configuration of the duplexer according to the first preferred embodiment of the present invention.

FIG. 3 is a schematic plan cross-sectional view of a positional construction at an intermediate height of the package for the duplexer shown in FIG. 2.

FIG. 4 is a schematic plan cross-sectional view of the duplexer according to the first preferred embodiment of the present invention.

FIG. 5(a) is a plan view of an surface acoustic wave element chip used in the first preferred embodiment, and FIGS. 5(b) and 5(c) are respectively schematic plan views showing electrode constructions of a serial arm resonator and a parallel arm resonator.

FIG. 6 is a graph illustrating a frequency characteristic of a transmission-side band filter of the duplexer according to the first preferred embodiment of the present invention.

FIG. 7 is a graph illustrating a frequency characteristic of a reception-side band filter of the duplexer according to the first preferred embodiment of the present invention.

FIG. 8 is a graph illustrating an isolation characteristic of the duplexer according to the first preferred embodiment of the present invention.

FIG. 9 is a graph illustrating a frequency characteristic of a transmission-side band filter of a duplexer using an LiNbO₃ substrate with a cut angle of 45° prepared for comparison.

FIG. 10 is a graph illustrating a frequency characteristic of a reception-side band filter of a duplexer using the LiNbO₃ substrate with a cut angle of 45° prepared for comparison.

FIG. 11 is a graph illustrating an isolation characteristic of a duplexer using the LiNbO₃ substrate with a cut angle of 45°.

FIG. 12 is a graph illustrating a relation between a cut angle of an LiNbO₃ substrate and an electromechanical coupling coefficient.

FIG. 13 is a circuit diagram of a circuit configuration of a duplexer according to a second preferred embodiment of the present invention.

FIG. 14 is a graph illustrating a frequency characteristic of a reception-side band filter of the duplexer according to the second preferred embodiment of the present invention.

FIG. 15 is a graph illustrating a frequency characteristic of a transmission-side band filter of the duplexer according to the second preferred embodiment of the present invention.

FIG. 16 is a graph illustrating an isolation characteristic of the duplexer according to the second preferred embodiment of the present invention.

FIG. 17 is a schematic plan view for describing a specific configuration of the duplexer according to the second preferred embodiment of the present invention.

FIG. 18 is a circuit diagram for describing a modified example of the duplexer according to the second preferred embodiment of the present invention.

FIG. 19 is a simplified frontal cross-sectional view for describing a modified example of the duplexer according to the first preferred embodiment of the present invention.

FIG. 20 is a circuit diagram for describing an example of a related-art duplexer.

FIG. 21 is a graph illustrating a frequency characteristic of a transmission-side band filter of the related-art duplexer.

FIG. 22 is a graph illustrating a frequency characteristic of a reception-side band filter of the related-art duplexer.

FIG. 23 is a graph illustrating an isolation characteristic of the related-art duplexer.

### DETAILED DESCRIPTION OF PREFERRED EMBODIMENTS

Hereinafter with reference to the drawings, the present invention will be described with reference to specific preferred embodiments of the present invention.

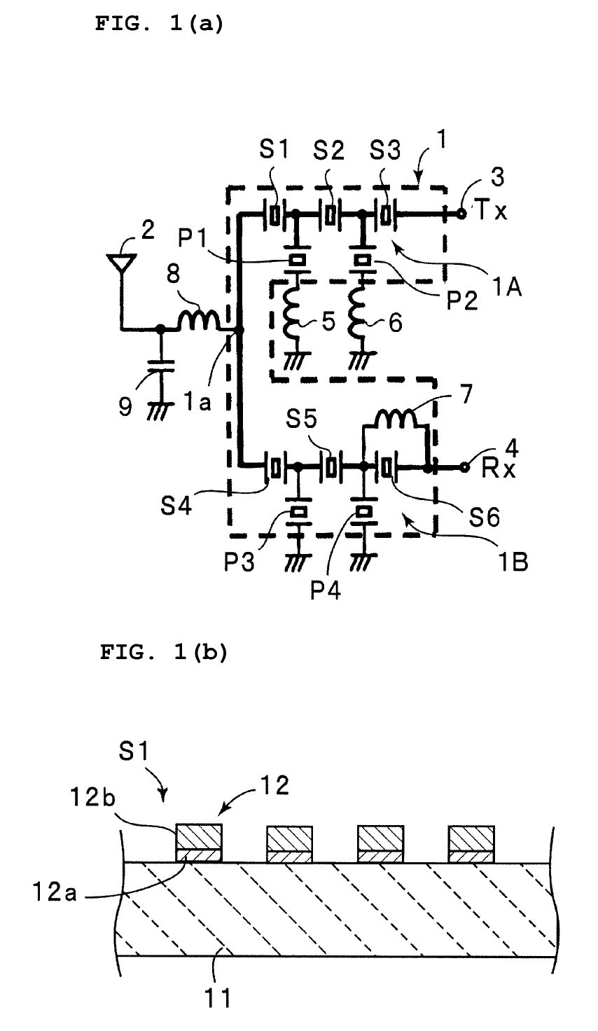

FIG. 1 is a circuit diagram of a circuit configuration of a duplexer according to a first preferred embodiment of the present invention. It should be noted that an area surrounded by a dashed line corresponds to a duplexer area of this preferred embodiment in FIG. 1.

A duplexer 1 includes an antenna terminal 1a. Connected to the antenna terminal 1a are a transmission-side band filter 1A and a reception-side band filter 1B. The transmission-side band filter 1A is connected to a transmission terminal 3, and the reception-side band filter 1B is connected to a reception terminal 4.

In the transmission-side band filter 1A, a plurality of surface acoustic wave resonators are connected to define a ladder circuit. That is, the transmission-side band filter 1A includes a plurality of serial arm resonators S1 to S3, each of which includes a surface acoustic wave resonator and parallel arm resonators P1 and P2. Inductances 5 and 6 are connected between the parallel arm resonators P1 and P2 and a ground potential. The inductances 5 and 6 define second inductances of the present invention. It should be noted that according to this preferred embodiment, the inductances 5 and 6 are preferably defined by a wire bonding or a line arranged in the duplexer 1.

On the other hand, the reception-side band filter 1B includes a plurality of surface acoustic wave resonators that are connected to define a ladder circuit. Herein, a plurality of serial arm resonators S4 to S6 and a plurality of parallel arm resonators P3 and P4 are provided. Then, the serial arm resonator S6 in the last pole is connected in parallel with respect to an first inductance 7. With the connection of the first inductance 7, in the reception-side band filter, an attenuation pole is provided on the low pass side of the pass band, and accordingly the increase in the attenuation of the reception-side band filter 1B on the low pass side of the pass band is achieved.

The first and second inductances 5 to 7 may be defined by an external coil component.

However, the first and second inductances 5, 6 and 7 are preferably defined by at least one of the wire bonding and the line arranged in the duplexer. In that case, additional external components, such as the coil component, are not necessary. Therefore, the first and second inductances 5 to 7 can be provided without increasing the number of components of the duplexer 1.

On the other hand, connected between the antenna terminal 1a and an antenna 2 is a third inductance 8. Then, connected between a connection point between the third inductance 8 and the antenna 2 and the ground potential is a capacitor 9. The third inductance 8 and the capacitor 9 are defined by an external component attached to the duplexer 1. Examples of such external component include a chip coil and a chip capacitor.

According to this preferred embodiment, as described above, the first and second inductances 5 to 7 are defined by the wire bonding and/or the line in the duplexer, whereby the package area is reduced to about 90.25% and the mounting area is reduced to about 80% as compared to the related-art products.

FIG. 1(b) is a schematic frontal cross-sectional view showing the electrode construction in the duplexer 1 described above, and a portion of the electrode of the serial arm resonator S1 is schematically shown as a representative example of the electrode construction. The serial arm resonator S1 includes a 47° to 58° rotated, Y-cut, X-propagating LiNbO₃ substrate 11 and an IDT electrode 12 provided on the LiNbO₃ substrate 11. Then, the IDT electrode 12 includes a Ti foundation electrode layer foundation electrode layer formed through epitaxial growth on the LiNbO₃ substrate and an Al electrode layer 12b formed through epitaxial growth on the Ti foundation electrode layer foundation electrode layer. Furthermore, the (111) face of the Al electrode layer, the (001) face or the (100) face of the Ti foundation electrode layer, and the (001) face of the LiNbO₃ substrate are aligned in parallel. Therefore, as the IDT electrode 12 has a similar construction to that of the IDT electrode of the surface acoustic wave elements described in Patent Document 1 mentioned above, the electric power resistance is superior. It should be noted that although FIG. 1 (b) schematically shows the electrode construction of the serial arm resonator S1, the other serial arm resonators S2, S3, and S4 to S6 and the parallel arm resonators P1 to P4 are constructed by using the IDT electrode with the similar crystal structure. Therefore, the duplexer 1 has superior electric power resistance.

Next, a description will be given of a specific configuration of the duplexer 1 according to this preferred embodiment of the present invention.

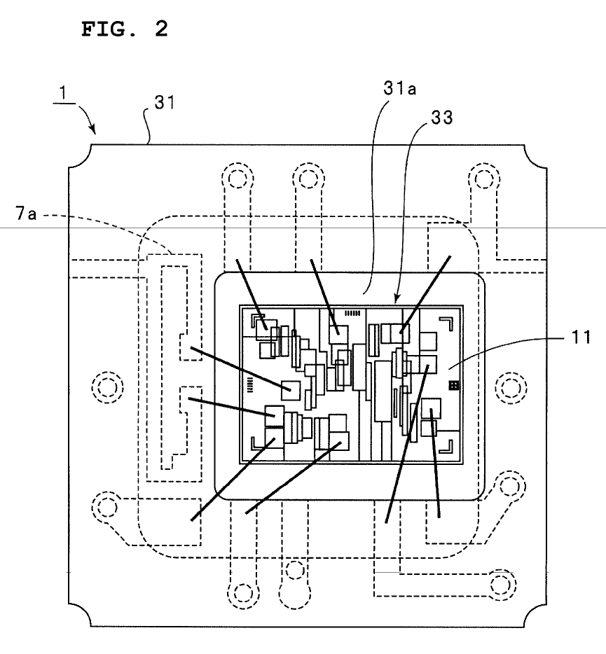

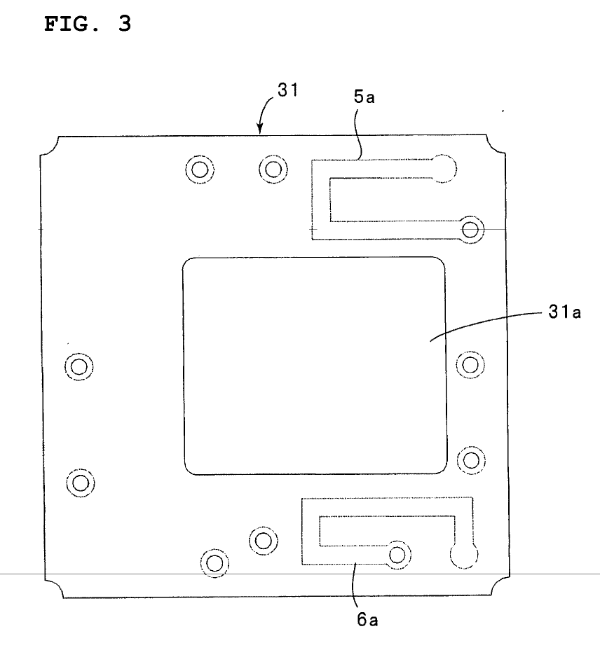

FIG. 2 is a specific plan view of the duplexer according to the first preferred embodiment, and FIG. 3 is a plan cross-sectional view thereof at the intermediate height.

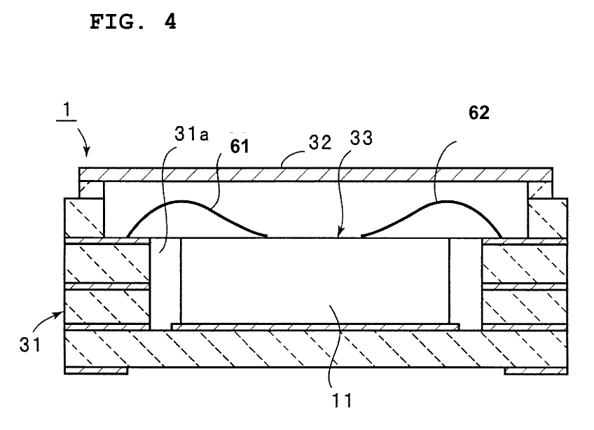

The duplexer 1 includes a package 31. The package 31 is a multilayer package substrate including an insulating ceramic, such as aluminum. That is, as shown in a schematic cross-sectional view of FIG. 4, the package 31 is a multilayer package substrate including a plurality of laminated insulating ceramic layers.

The package 31 includes a concave portion 31a that is open upward. As shown in FIG. 4, the concave portion 31a is closed by a cover member 32. Graphic representation for the cover member 32 is omitted in FIG. 2. In the concave portion 31a, an surface acoustic wave element chip 33 is accommodated as shown in FIG. 2.

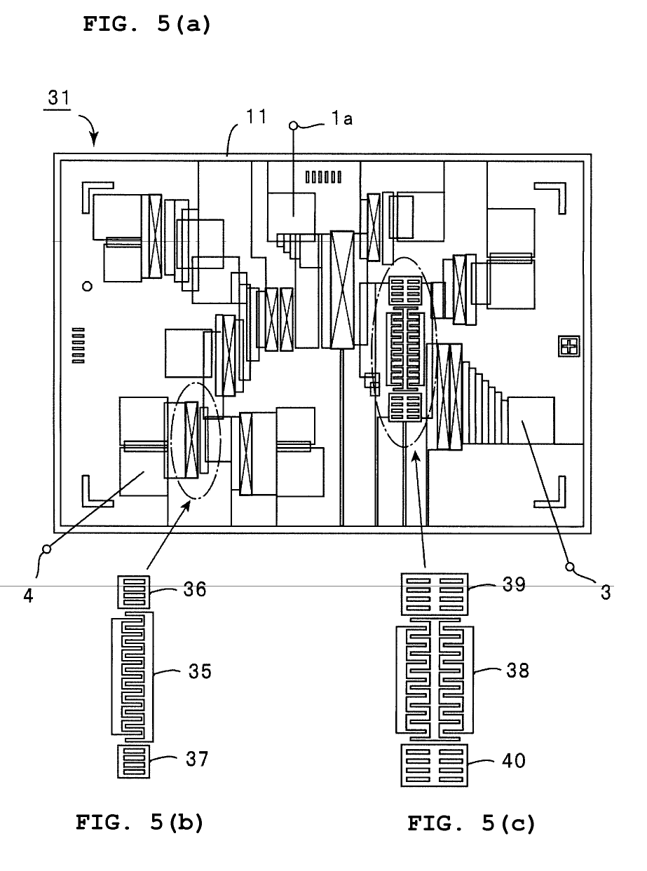

The surface acoustic wave element chip 33 is shown in a plan view of FIG. 5(a). The surface acoustic wave element chip 33 preferably includes a substantially rectangular LiNbO₃ substrate 11. As described above, according to the first preferred embodiment, as the LiNbO₃ substrate 11, a 55° rotated, Y-cut LiNbO₃ substrate is preferably used.

Then, the IDT electrode with the cross-sectional construction shown in FIG. 1(b) is provided on the LiNbO₃ substrate 11 to define the serial arm resonators S1 to S6 and the parallel arm resonators P1 to P4. In FIG. 5(a), the graphic representation for the electrode construction of the serial arm resonator and the parallel arm resonator is simplified, whereas FIG. 5(b) shows the electrode construction of the serial arm resonator S6 in a schematic plan view. That is, as shown in FIG. 5(b), the serial arm resonator S6 is a one terminal pair surface acoustic wave resonator including the IDT electrode 35 and reflectors 36 and 37 on both sides of the surface acoustic wave propagating direction of the IDT electrode 35.

It should be noted that each of other serial arm resonators S3 and S5 and the parallel arm resonators P1 to P4 is similarly composed of a one terminal pair surface acoustic wave resonator by arranging reflectors on both sides in the direction of the surface acoustic wave propagating direction of the IDT electrode. On the other hand, as shown in FIG. 5(c), the serial arm resonator S2 includes an IDT electrode 38 to which a pair of IDT electrodes are connected and reflectors 39 and 40 arranged on both sides in the direction of the surface acoustic wave propagating direction of the IDT electrode 38. That is, the serial arm resonator S2 includes two serial arm resonators S2a and S2b. In a similar manner, the serial arm resonator S1 and the serial arm resonator S4 also includes serial arm resonators S1a and S1b and serial arm resonators S4a and S4b that are respectively connected.

However, in various preferred embodiments of the present invention, the serial arm resonator or the parallel arm resonator defining the ladder circuit may include a surface acoustic wave resonator having a single pole construction or a plural pole construction with the any suitable number of poles.

As shown in FIG. 5 (a), the serial arm resonators S1 to S6 and the parallel arm resonators P1 to P4 are provided on the LiNbO₃ substrate 11, and are respectively electrically connected to define the transmission-side band filter 1A and the reception-side band filter 1B. That is, as shown in FIG. 1, in the transmission-side band filter 1A, the serial arm resonators S1 to S3 and the parallel arm resonators P1 and P2 are electrically connected to define a ladder circuit. In a similar manner, in the reception-side band filter 1B, the serial arm resonators S4 to S6 and the parallel arm resonators P1 and P2 are electrically connected to define a ladder circuit.

Furthermore, according to the first preferred embodiment, the second inductances 5 and 6 are defined by the bonding wire and the coil patterns in the package. To be more specific, as shown in FIG. 3, the inductances 5 and 6 are defined by coil patterns 5a and 6a provided at the intermediate height positions of the package 31 and bonding wires 61 and 62 shown in FIG. 4. Then, the first inductance 7 is defined by the bonding wire and the coil patterns in the package shown in FIG. 2. In this manner, as the coil patterns 5a, 6a, and 7a and the bonding wires 61 and 62 provided inside the package are used, the first and second inductances 5, 6 and 7 are provided without increasing the number of components.

The duplexer 1 according to this preferred embodiment is not only superior in the electric power resistance, and but also uses a 47° to 58° rotated, Y-cut, X-propagating LiNbO₃ substrate 11, whereby the out-of-band attenuation is sufficiently large and the isolation characteristic is satisfactory. This will be described on the basis of specific experimental examples.

Each of the serial arm resonators S1 to S6 and the parallel arm resonators P1 to P4 is defined by the surface acoustic wave resonator having the IDT electrode of the above-mentioned construction provided on the 55° rotated, Y-cut, X-propagating LiNbO₃ substrate 11. It should be noted that the thickness of the Ti foundation electrode layer is set to about 10 nm and the thickness of the Al electrode layer is set to about 92 nm.

Specifications of the serial arm resonators S1 to S6 and the parallel arm resonators P1 to P4 are shown in Tables 1 and 2 below. In the Tables 1 and 2 below, the number of the electrode fingers of the reflector, the duty ratio of the IDT electrode, the size of a gap between the IDT and the reflector, the cross width and log of the electrode fingers of the IDT electrode, and a wavelength λ are shown.

TABLE 1

| | The number of | | | Cross | | |
|---|---|---|---|---|---|---|
| | reflector fingers | Duty ratio | Gap | width | IDT log | λ |
| S1 | 15 | 0.4 | 0.5 | 40 | 140 | 2.1743 |
| P1 | 15 | 0.4 | 0.45 | 40 | 80 | 2.3016 |
| S2a | 15 | 0.4 | 0.5 | 55 | 200 | 2.1533 |
| S2b | 15 | 0.4 | 0.5 | 55 | 200 | 2.1533 |
| P2 | 15 | 0.4 | 0.45 | 40 | 80 | 2.2957 |
| S3a | 15 | 0.4 | 0.5 | 40 | 160 | 2.1743 |
| S3b | 15 | 0.4 | 0.5 | 40 | 160 | 2.1743 |

TABLE 2

| | The number of | | | Cross | | |
|---|---|---|---|---|---|---|
| | reflector fingers | Duty ratio | Gap | width | IDT log | λ |
| S4a | 15 | 0.4 | 0.5 | 40 | 65 | 1.9648 |
| S4b | 15 | 0.4 | 0.5 | 40 | 65 | 1.9648 |
| P3 | 15 | 0.4 | 0.45 | 65 | 70 | 2.1146 |
| S5 | 15 | 0.4 | 0.5 | 50 | 80 | 1.9703 |
| P4 | 15 | 0.4 | 0.45 | 55 | 70 | 2.1146 |
| S6 | 15 | 0.4 | 0.5 | 50 | 85 | 2.0057 |

Then, the transmission-side band filter 1A and the reception-side band filter 1B are constructed such that the intermediate frequency of the transmission-side band filter 1A is set to about 1945 MHz and the intermediate frequency of the reception-side band filter 1B is set to about 2140 MHz. A coil pattern with the inductance of about 2.7 nH is provided as the coil pattern to construct the second inductances 5 and 6 so that the inductance of about 3.3 nH is attained by the coil pattern and the bonding wire with the inductance of about 0.6 nH. Also, regarding the first inductance 7, the inductance value of the coil pattern is set to about 0.8 nH and the inductance value of the bonding wire the inductance value is set to about 1.2 nH, whereby the inductance value of the first inductance 7 is set to about 1.9 nH.

The value of the third inductance 8 is set to about 3.3 nH and the capacity of the capacitor 9 is set to about 1.3 pF. Frequency characteristics of the duplexer 1 thus constructed according to this preferred embodiment were measured. FIGS. 6 to 8 show the results. Then, the pass band of the transmission-side band filter 1A is 1920 to 1980 MHz and the pass band of the reception-side band filter 1B is 2110 to 2170 MHz.

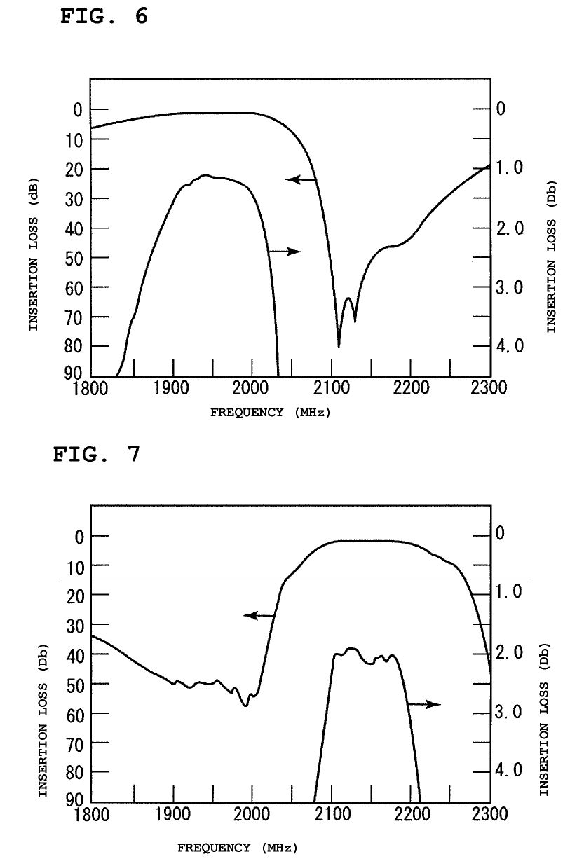

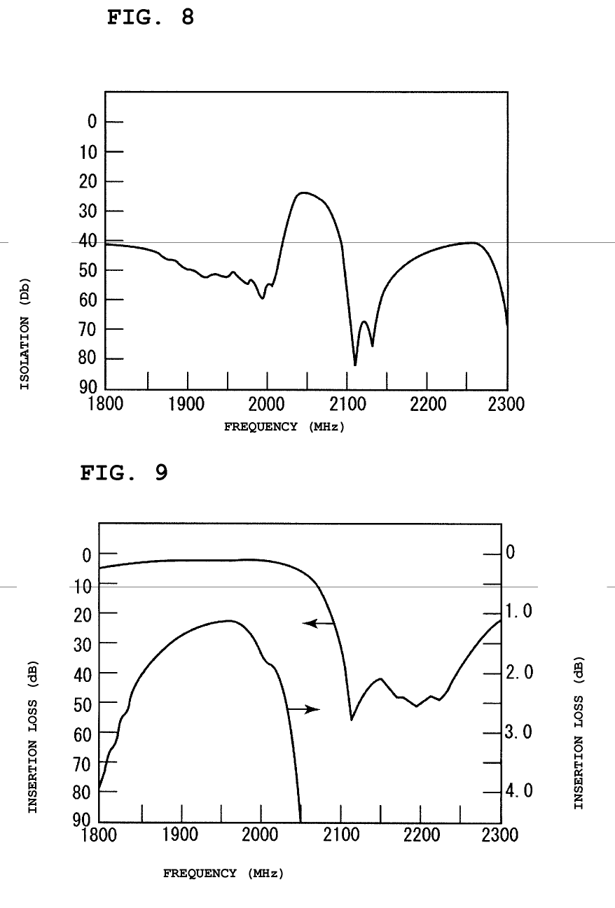

FIG. 6 shows a frequency characteristic of the transmission-side band filter 1A, FIG. 7 shows a frequency characteristic of the reception-side band filter 1B, and FIG. 8 shows the isolation characteristic of the duplexer. It should be noted that, the frequency characteristics on the lower sides in FIGS. 6 and 7 represent the frequency characteristics in pass bands based on the right-hand side scale shown through magnification of the corresponding frequency characteristics.

As is apparent from FIG. 6, in the transmission-side band filter 1A, the attenuation on the high pass side of the pass band (reception-side band) is about 47 dB, and the value is substantially greater than 40 dB as required. Similarly, as is apparent from FIGS. 7 and 8, in the pass band of the reception-side band filter 1B, the attenuation of the isolation characteristic is at least about 48 dB.

That is, as is apparent from FIGS. 6 to 8, in the duplexer, not only the electric power resistance is increased, but also, the out-of-band attenuation is increased. In particular, the attenuation on the high pass side of the pass band of the transmission-side band filter 1A is significantly improved, and at the same time, the isolation characteristic is also significantly improved.

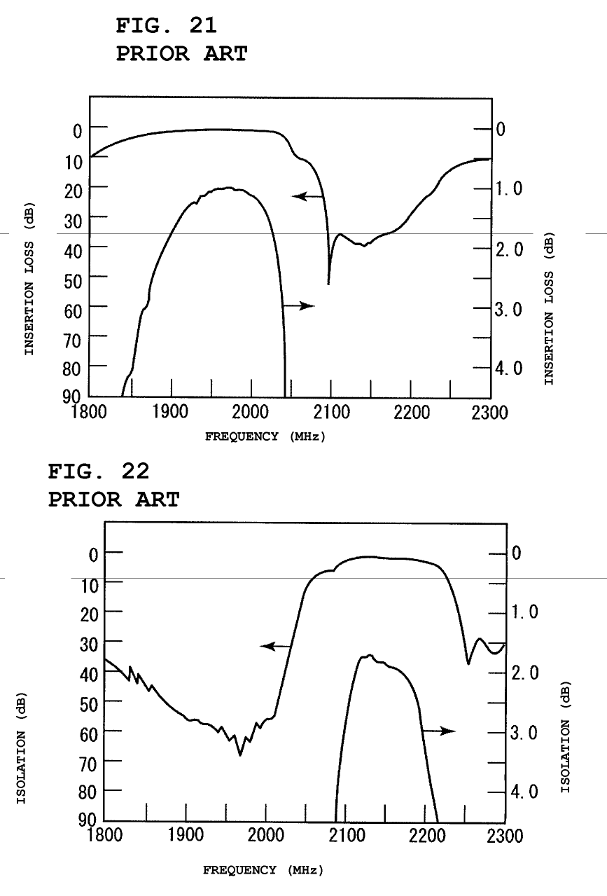

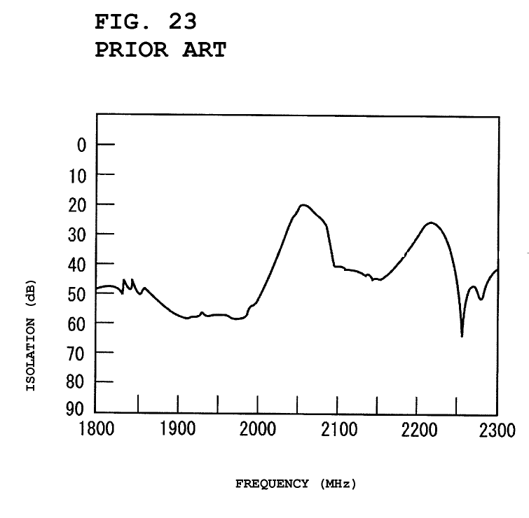

As described above, in the duplexer 1, the out-of-band attenuation and the isolation characteristic is significantly improved because a LiNbO₃ substrate with a cut angle falling in a range from about 47° to about 58° is used for the LiNbO₃ substrate 11. This will be described on the basis of specific experimental examples. The characteristics of the above-described related-art product shown in FIGS. 21 to 23 correspond to the characteristics of the duplexer similarly constructed as in the first preferred embodiment except that the cut angle of the LiNbO₃ substrate is 64° and the serial arm resonators S1 to S3 and S4 to S6 and the parallel arm resonators P1, P2, P3, and P4 are constructed as shown in Tables 3 and 4 below. At this time, when the cut angle of the substrate is varied, it is necessary to vary the values of the duty ratio, the cross width, and other parameters with which optimal characteristics (characteristics at low loss and high attenuation) can be obtained. Therefore, to conduct characteristic comparisons in view of the cut angle, the optimal characteristics in the 55° rotated, Y-cut, X-propagating LiNbO₃ substrate and the optimal characteristics in the 64° rotated, Y-cut, X-propagating LiNbO₃ substrate must be compared with each other. For this reason, the duty ratio and the cross width shown in Tables 1 and 2, with which the optimal characteristics are obtained in the 55° rotated, Y-cut, X-propagating LiNbO₃ substrate are different from the duty ratio and the cross width shown in Tables 3 and 4, with which the optimal characteristics are obtained in the 64° rotated, Y-cut, X-propagating LiNbO₃ substrate. Then, as described with reference to FIGS. 21 to 23, in the duplexer 201, the pass band attenuation and the isolation characteristic of the transmission-side band filter are not sufficiently large.

TABLE 3

| | The number of | | | Cross | | |
|---|---|---|---|---|---|---|
| | reflector fingers | Duty ratio | Gap | width | IDT log | λ |
| S1 | 14 | 0.390 | 0.5 | 60 | 196 | 2.1450 |
| P1 | 14 | 0.347 | 0.5 | 54.3 | 92 | 2.2525 |
| S2a | 14 | 0.390 | 0.5 | 32.5 | 200 | 2.1450 |
| S2b | 14 | 0.390 | 0.5 | 92 | 200 | 2.1450 |
| P2a | 14 | 0.347 | 0.5 | 41.9 | 90 | 2.2526 |
| P2b | 14 | 0.347 | 0.5 | 41.9 | 90 | 2.2526 |
| S3a | 14 | 0.390 | 0.5 | 40 | 165 | 2.1450 |
| S3b | 14 | 0.390 | 0.5 | 36 | 165 | 2.1450 |

TABLE 4

| | The number of | | | Cross | | |
|---|---|---|---|---|---|---|
| | reflector fingers | Duty ratio | Gap | width | IDT log | λ |
| S4a | 14 | 0.389 | 0.5 | 31.5 | 125 | 1.9559 |
| S4b | 14 | 0.389 | 0.5 | 35 | 125 | 1.9559 |
| S4c | 14 | 0.389 | 0.5 | 40 | 125 | 1.9559 |
| P3 | 14 | 0.361 | 0.5 | 41.2 | 114 | 2.0896 |
| S5 | 14 | 0.390 | 0.5 | 28 | 116 | 1.9967 |
| P4 | 14 | 0.361 | 0.5 | 41.2 | 114 | 2.0896 |
| S6a | 14 | 0.390 | 0.5 | 75 | 165 | 1.9967 |
| S6b | 14 | 0.390 | 0.5 | 53 | 165 | 1.9967 |

On the other hand, for further comparison, a duplexer according the preferred embodiment described above except that the cut angle of the LiNbO₃ substrate is 45° is constructed and the frequency characteristic is measured. FIGS. 9 to 11 show the results.

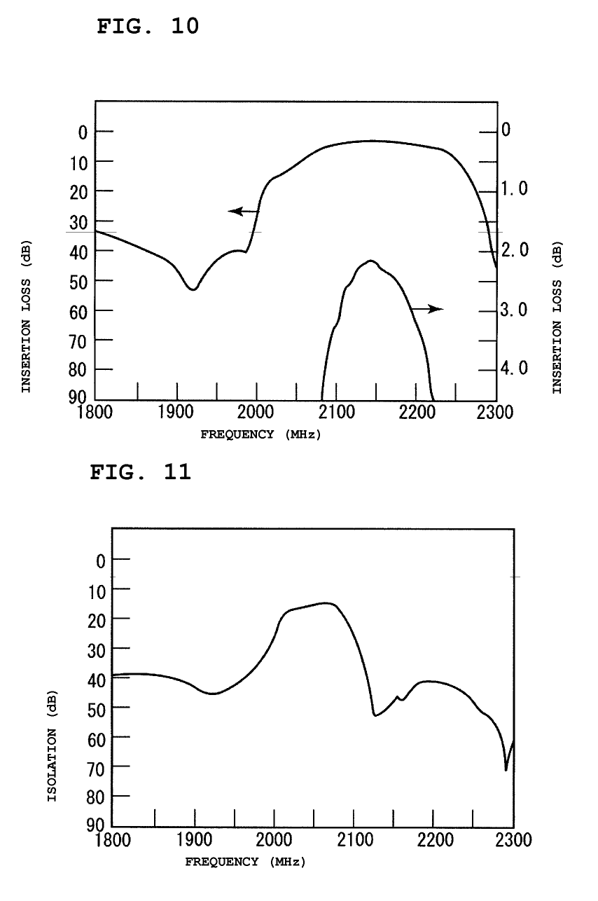

FIG. 9 shows the frequency characteristic of a transmission-side band filter of a duplexer for the comparative example, FIG. 10 shows the frequency characteristic of a reception-side band filter, and FIG. 11 shows the isolation characteristic. It should be noted that the frequency characteristics on the lower sides in FIGS. 9 and 10 represent the frequency characteristics in pass bands based on the right-hand side scale shown through magnification of the corresponding frequency characteristics.

As is apparent from FIG. 9, when the LiNbO₃ substrate with a cut angle of 45° is used, the attenuation on the high pass side of the pass band the reception-side band filter is slightly above 40 dB, and it is understood that the attenuation is lower as compared to the duplexer 1 according to the preferred embodiment described above. Also, from FIGS. 10 and 11, the isolation characteristic of the reception-side band filter is also slightly above 40 dB, and it is understood that the isolation characteristic is not sufficiently large.

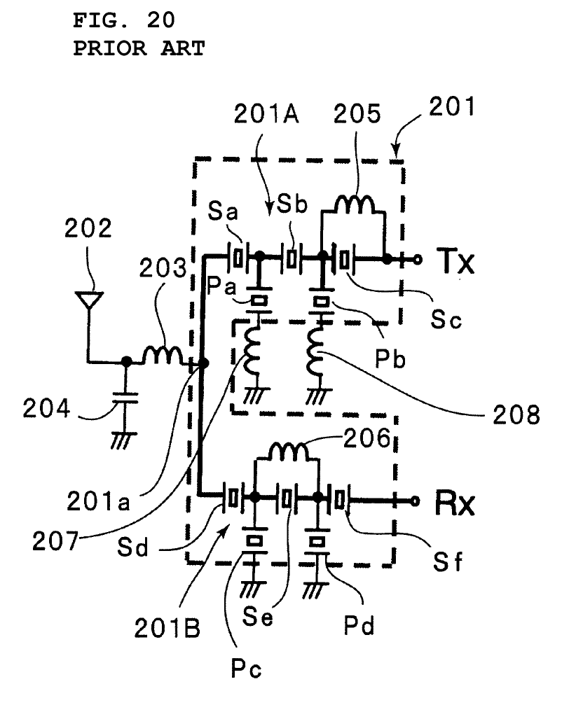

As is apparent by comparing the result of the preferred embodiment described above with the result from the comparative examples using the LiNbO₃ substrate with the cut angle of 45° shown in FIGS. 9 to 11 and the result from the related-art examples using the LiNbO₃ substrate with the cut angle of 64° described with reference to FIGS. 20 to 23, when the rotation angle of the LiNbO₃ substrate is set to about 55°, the out-of-band attenuation and the isolation characteristic are sufficiently large in the duplexer 1. Then, based on the experiments conducted by the inventors of the present invention, in the duplexer 1 described above, when the cut angle of the LiNbO₃ substrate is set with in a range from about 47° to about 58°, satisfactory characteristics are obtained, as in the preferred embodiment described above.

As shown in FIGS. 9 to 11, as the cut angle is decreased, the out-of-band attenuation cannot be set sufficiently large. This is because, as the cut angle is decreased, the insertion loss is increased, and an attenuation constant α is increases. As the electromechanical coupling coefficient is too large, steepness cannot be obtained, thereby degrading the attenuation (the band selectivity is degraded). Therefore, in consideration with the change in characteristics due to the temperature, a sufficiently large out-of-band attenuation and isolation characteristic cannot be obtained.

In addition, as the cut angle is decreased, an angle between the Y axis and a normal to the substrate decreases, and epitaxial growth of electrode films is difficult. Therefore, the formation of the electrode with the high electric power resistance is also difficult. The lower limit of the cut angle at which the electrode films can be formed through the epitaxial growth is about 47° based on the experiments conducted by the inventors of the present invention. That is, when the LiNbO₃ substrate whose cut angle is less than about 47° is used, it was impossible to form the electrode films through the epitaxial growth. Therefore, as described above, the lower limit of the cut angle for the LiNbO₃ substrate is about 47°.

On the other hand, in consideration with the use temperature range of the duplexer, the upper limit of the cut angle which satisfies the attenuation and the isolation characteristic is about 58°. When the LiNbO₃ substrate whose cut angle is greater than about 58° is used, the out-of-band attenuation cannot be set sufficiently large. Therefore, for example, in the transmission-side band filter, the inductance element connected in parallel with respect to the serial arm resonators cannot be omitted.

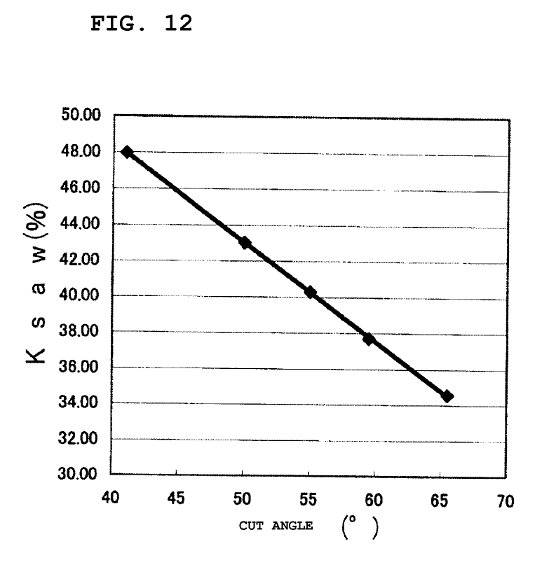

As described above, according to this preferred embodiment, the electrode for increasing the electric power resistance uses the rotated, Y-cut, X-propagating LiNbO₃ substrate with a cut angle of about 47° to about 58°, the out-of-band attenuation and the isolation characteristic are effectively increased. In the related art, it has been thought that when the LiNbO₃ substrate is used as a piezoelectric substrate for the surface acoustic wave resonator, a large cut angle is preferable. FIG. 12 shows a relationship between the cut angle of the rotated, Y-cut LiNbO₃ substrate and the electromechanical coupling coefficient of the surface acoustic wave. Herein, the duty ratio of the electrode is set to about 0.4 and the normalized thickness of the electrode (H/λ) is set to about 5.15. It should be noted that H denotes the thickness of the electrode and λ denotes the wavelength of the surface acoustic wave.

As is apparent from FIG. 12, as the cut angle exceeds 40° to 60° and is further increased, an electromechanical coupling coefficient K becomes small. Therefore, to enlarge the out-of-band attenuation in the neighborhood of the band, it has been thought that desirably, the cut angle is set to be large and the band width is set to be small. That is, in the related art, to enlarge the out-of-band attenuation, it has been thought that larger the cut angle of the rotated, Y-cut LiNbO₃ substrate are more desirable.

Also, in the related art, it has been thought that when the rotated, Y-cut LiNbO₃ substrate is used, as the cut angle is increased, the propagation loss α is decreased, whereby the insertion loss can be set smaller and at the same time the out-of-band attenuation can be increased.

That is, despite the technical common knowledge of the related art in which it is desirable to set the cut angle as large as possible when the duplexer is constructed using the rotated, Y-cut LiNbO₃ substrate to enlarge the out-of-band attenuation, that is, the cut angle is desirably larger than about 60°, the present invention sets the cut angle to equal to or less than about 58°. Then, by setting the cut angle in the particular range from about 47° to about 58°, the electrode that is superior in electric power resistance can be provided, and, in addition, it is possible to set the out-of-band attenuation and the isolation characteristic to be sufficiently large.

Thus, according to the preferred embodiment described above, as the sufficient out-of-band attenuation is obtained, the number of the inductance elements used for ensuring the attenuation is reduced. That is, with the related-art duplexer shown in FIG. 20, while the inductance 205 is connected in parallel with respect to the serial arm resonator Sc in the transmission-side band filter 201A, it is possible to omit the inductance 205. Therefore, the size of the duplexer can be reduced.

However, as in the preferred embodiment described above, the first inductance 7 is connected in parallel with respect to the serial arm resonator S6, and accordingly, the out-of-band attenuation may be further increased. It should be noted that in the related art, even when the LiNbO₃ substrate whose cut angle is greater than about 60°, the sufficient out-of-band attenuation cannot be obtained, and it is impossible to omit the inductance 205 described above.

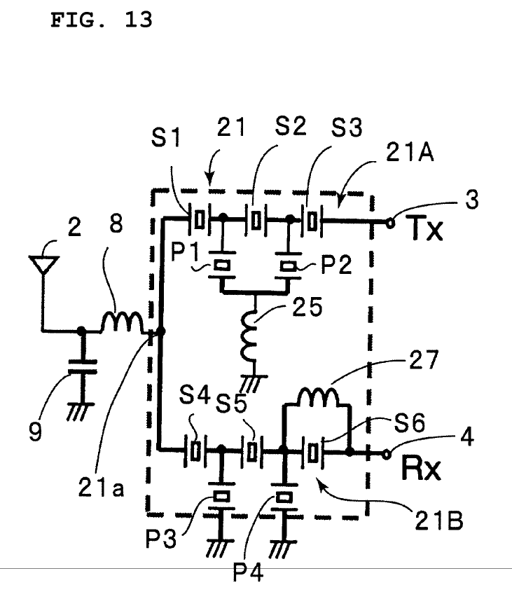

FIG. 13 is a circuit diagram for describing a duplexer according to a second preferred embodiment of the present invention. It should be noted that in FIG. 13 an area surrounded by a dashed line corresponds to a duplexer according to this preferred embodiment.

A duplexer 21 includes an antenna terminal 21a. Connected to the antenna terminal 21a are a transmission-side band filter 21A and a reception-side band filter 21B. The transmission-side band filter 21A is connected to the transmission terminal 3, and the reception-side band filter 21B is connected to the reception terminal 4. The transmission-side band filter 21A and the reception-side band filter 21B respectively include five surface acoustic wave resonators that are connected to define a ladder circuit similar to the transmission-side band filter 1A and the reception-side band filter 1B of the first preferred embodiment. Therefore, the same components will be given the same reference numerals and the description for the first preferred embodiment is to be incorporated herein.

According to the second preferred embodiment, in the transmission-side band filter 21A, a second inductance 25 is connected between the parallel arm resonators P1 and P2 and the ground potential. Herein, the second inductance 25 is provided in the duplexer 21.

The second inductance 25 may be defined by the wire bonding or the line used in the duplexer 21. However, the second inductance 25 may be defined by the coil component or other suitable component, similar to the component externally attached to the duplexer 21.

In the reception-side band filter 21B, a first inductance 27 is connected in parallel with respected to the serial arm resonator S6 in the last pole. With the connection of the first inductance 27, in the reception-side band filter 21B, the attenuation pole is provided on the low pass side of the pass band. Accordingly, the increase in the attenuation of the reception-side band filter 21B on the low pass side of the pass band is achieved.

The first inductance 27 may be defined by the coil component or may be defined by the wire bonding or the line in the duplexer.

In the duplexer 21, the third inductance 8 and the capacitor 9 are connected between the antenna terminal 21a and the antenna 2, as in the first preferred embodiment.

In this preferred embodiment, when the first and second inductances 25 and 27 are defined by at least one of the wire bonding and the line arranged in the duplexer, additional components are not required. Therefore, the first and second inductances 25 and 27 are provided without increasing the number of components.

According to this preferred embodiment, the duplexer 21 includes a 50° rotated, Y-cut, X-propagating LiNbO₃ substrate, the serial arm resonators S1 to S6 and the parallel arm resonators P1 to P4 are constructed in the same manner as in the first preferred embodiment. Each of the serial arm resonators S1 to S6 and the parallel arm resonators P1 to P4 includes IDT electrodes having the electrode construction in which the Ti foundation electrode layer and the Al electrode layer are laminated. Therefore, a description of the construction of the IDT electrode will be omitted by incorporating the description of the electrode construction with reference to FIG. 1(b) in the first preferred embodiment.

The duplexer 21 of the second preferred embodiment described above is fabricated using the following procedure, and the frequency characteristic is measured.

The serial arm resonators S1 to S6 and the parallel arm resonators P1 to P4 are constructed as shown in Tables 5 and 6 below.

In the preferred embodiment described below, the serial arm resonators S1, S2, and S4 have a double pole construction including the serial arm resonators S1a and S1b, S2a and S2b, and S4a and S4b.

TABLE 5

| | The number of | | | Cross | | |
|---|---|---|---|---|---|---|
| | reflector fingers | Duty ratio | Gap | width | IDT log | λ |
| S1 | 15 | 0.4 | 0.5 | 44 | 120 | 2.187421 |
| P1 | 15 | 0.4 | 0.4 | 44 | 80 | 2.322526 |
| S2a | 15 | 0.4 | 0.5 | 45 | 100 | 2.160974 |
| S2b | 15 | 0.4 | 0.5 | 45 | 100 | 2.160974 |
| P2 | 15 | 0.4 | 0.4 | 44 | 80 | 2.328572 |
| S3a | 15 | 0.4 | 0.5 | 44 | 200 | 2.187421 |
| S3b | 15 | 0.4 | 0.5 | 44 | 200 | 2.187421 |

TABLE 6

| | The number of | | | Cross | | |
|---|---|---|---|---|---|---|
| | reflector fingers | Duty ratio | Gap | width | IDT log | λ |
| S4a | 15 | 0.4 | 0.5 | 35 | 65 | 1.958722 |
| S4b | 15 | 0.4 | 0.5 | 35 | 65 | 1.958722 |
| P3 | 15 | 0.4 | 0.45 | 50 | 90 | 2.103972 |
| S5 | 15 | 0.4 | 0.5 | 30 | 60 | 1.964194 |
| P4 | 15 | 0.4 | 0.45 | 45 | 70 | 2.099018 |
| S6 | 15 | 0.4 | 0.5 | 50 | 85 | 2.003944 |

The second inductance 25 is defined by the bonding wire in the duplexer 21, and the inductance value is set to about 0.6 nH. The first inductance 27 is defined by the coil pattern and the bonding wire provided inside the duplexer 21. The inductance value of the coil pattern is set to about 0.8 nH and the inductance value of the bonding wire is set to about 1.2 nH. That is, the inductance 27 is configured to have the inductance value of about 2.0 nH.

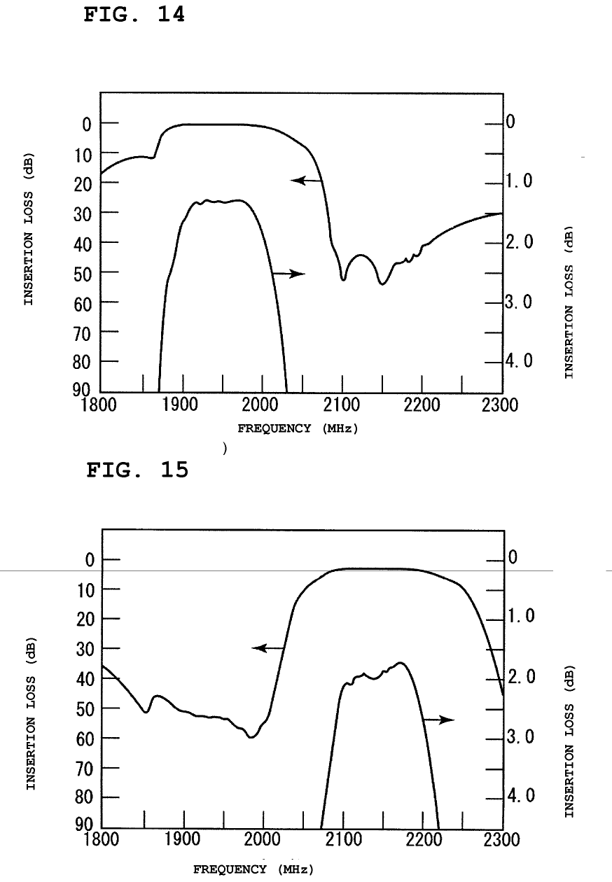

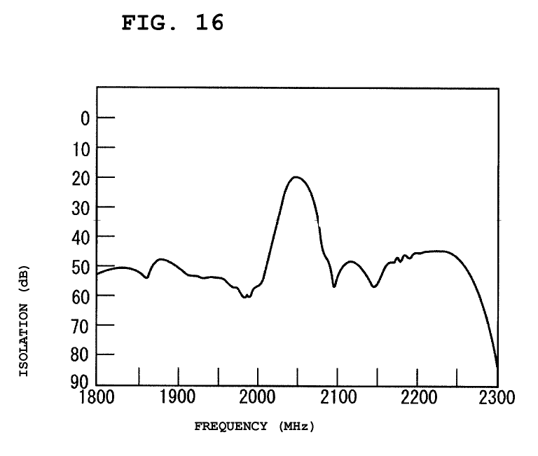

The inductance value of the inductance 8 externally attached is set to about 3.3 nH, and the electrostatic capacity of the capacitor 9 is set to about 1.3 pF. Frequency characteristics of the duplexer 21 constructed as described above are shown in FIGS. 14 to 16. FIG. 14 shows a frequency characteristic of the transmission-side band filter of the duplexer 21, FIG. 15 shows a frequency characteristic of the reception-side band filter, and FIG. 16 shows the isolation characteristic. It should be noted that the frequency characteristics on the lower sides in FIGS. 14 and 15 represent the frequency characteristics in pass bands based on the right-hand side scale shown through magnification of the corresponding frequency characteristics.

As is apparent from FIG. 14, even when the LiNbO₃ substrate with a cut angle of 50° is used, as in the case of the first preferred embodiment, the attenuation on the high pass side of the pass band (reception-side band) of the transmission-side band filter is set to a value greater than about 40 dB. Also, as is apparent from FIGS. 15 and 16, the isolation characteristic in the reception-side band is also substantially greater than 40 dB.

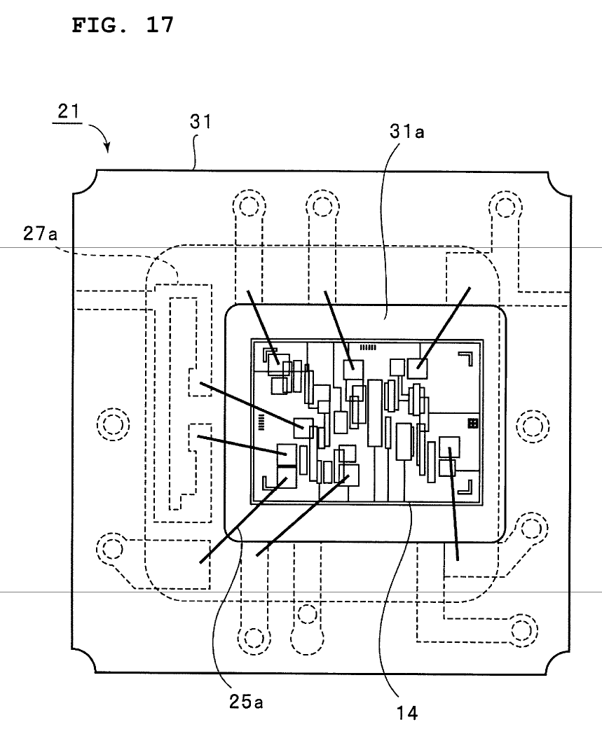

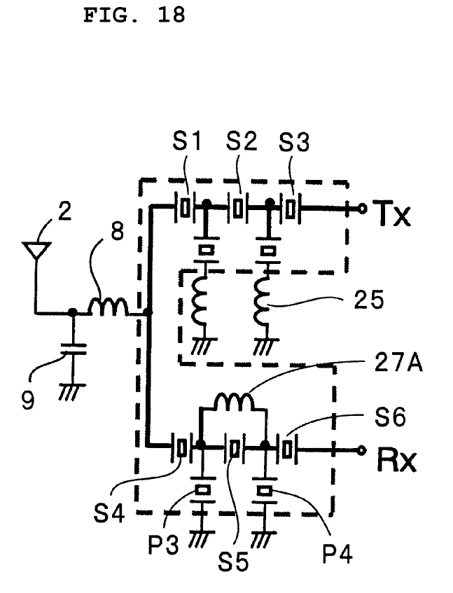

FIG. 17 is a schematic plan view of the duplexer according to the second preferred embodiment. In the duplexer 21, as in the first preferred embodiment, the second inductance can be provided by a coil pattern 27a in the package 31. Also, by using a bonding wire 25a, the first inductance 25 is provided. In this manner, by providing the second and first inductances 25 and 27 of the coil pattern and the bonding wire in the package of the duplexer 21, the size of the duplexer 21 is reduced without increasing in the number of components.

It should be noted that according to the second preferred embodiment, the first inductance 27 is connected in parallel with respect to the serial arm resonator S6 in the last pole of the reception-side band filter, but as shown in FIG. 18, the first inductance 27A may be connected in parallel with respect to the serial arm resonator S5 in the center.

Furthermore, according to the preferred embodiment described above, for achieving the impedance matching among the antenna, the transmission-side band filter, and the reception-side band filter, a matching circuit is provided in which an inductance is inserted between an antenna terminal and an antenna and a capacitor is connected between the antenna and a ground. However, as long as the impedance matching among the antenna, the transmission-side band filter, and the reception-side band filter can be achieved, any matching circuit other than the matching circuit described above may be used. For example, a matching circuit in which a capacitor is connected between an antenna terminal and an antenna and an inductance is connected between the antenna and a ground, or a matching circuit in which an inductance is simply connected between an antenna and a ground may also be used.

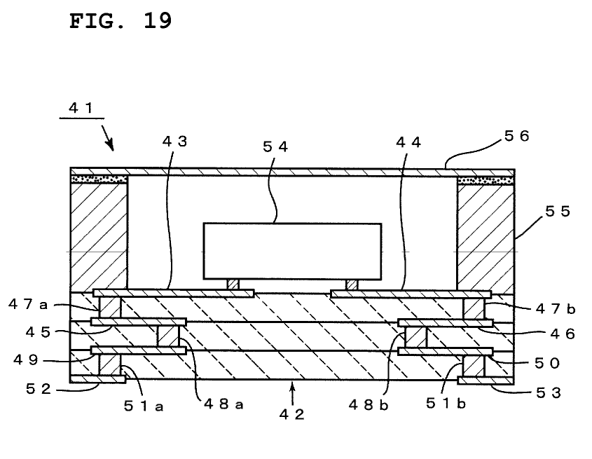

A duplexer 41 as a modified example shown in FIG. 19 uses a similar package configuration as that of the duplexer 1. However, herein, a multilayer substrate 42 is used as a package member. Electrode lands 43 and 44 are provided on the upper surface of the multilayer substrate 42. The electrode lands 43 and 44 are electrically connected to internal electrodes 45 and 46 arranged inside the multilayer substrate 42 via hole electrodes 47a and 47b so as to provide an inductance. In addition, the internal electrodes are connected to internal electrodes 49 and 50 via hole electrodes 48a and 48b so as to provide an inductance. The internal electrodes 49 and 50 are connected to terminal electrodes 52 and 53 via hole electrodes 51a and 51b. In this manner, the inductance may be provided inside the multilayer substrate 42, and a SAW chip including an LiNbO₃ substrate 54 constructed using a flip chip bonding method may be mounted on the multilayer substrate 42.

It should be noted that a frame member 55 made of the same material preferably is integrally provided on the upper surface of the multilayer substrate 42. Then, a cover member 56 for sealing the upper side of the frame member 55 is disposed on the upper surface of the frame member 55.

While preferred embodiments of the present invention have been described above, it is to be understood that variations and modifications will be apparent to those skilled in the art without departing the scope and spirit of the present invention. The scope of the present invention, therefore, is to be determined solely by the following claims.

1-5. (canceled)

6. A duplexer, comprising:
a transmission-side band filter including a plurality of surface acoustic wave resonators connected together to define a ladder circuit;
a reception-side band filter including a plurality of surface acoustic wave resonators connected together to define a ladder circuit; wherein
each of the plurality of surface acoustic wave resonators of the transmission-side band filter and the reception-side band filter includes a 47° to 58° rotated, Y-cut, X-propagating LiNbO₃ substrate and an IDT electrode provided on the LiNbO₃ substrate;
the IDT electrode includes a Ti foundation electrode layer disposed on the LiNbO₃ substrate and an Al electrode layer disposed on the Ti foundation electrode layer; and
a (111) face of the Al electrode layer, one of a (001) face and (100) face of the Ti foundation electrode layer, and a (001) face of the LiNbO₃ substrate are aligned in parallel.

7. The duplexer according to claim 6, where the Ti foundation electrode layer is an epitaxially grown electrode layer on the LiNbO₃ substrate and the Al electrode layer is an epitaxially grown electrode layer on the Ti foundation electrode layer.

8. The duplexer according to claim 6, wherein in the reception-side band filter, a first inductance is disposed in parallel with respect to at least one serial arm resonator connected to a serial arm of the ladder circuit among the plurality of surface acoustic wave resonators, and in the transmission-side band filter, a second inductance is disposed between a parallel arm resonator connected to a parallel arm of the ladder circuit among the plurality of surface acoustic wave resonators and a ground potential.

9. The duplexer according to claim 8, wherein the first inductance and the second inductance are respectively defined by at least one of a wire bonding used for electrical connection in the duplexer, a line embedded in the duplexer, and an external coil component.

10. The duplexer according to claim 8, wherein the first inductance and the second inductance are respectively defined by at least one of a wire bonding used for electrical connection in the duplexer and a line embedded in the duplexer.

11. The duplexer according to claim 6, wherein the transmission-side band filter includes three serial arm resonators and two parallel arm resonators defining the ladder circuit.

12. The duplexer according to claim 6, wherein the reception-side band filter includes three serial arm resonators and two parallel arm resonators defining the ladder circuit.

13. The duplexer according to claim 6, wherein the LiNbO₃ substrate is a 55° rotated, Y-cut, X-propagating LiNbO₃ substrate.

14. A communication device, comprising the duplexer according to claim 6, wherein the duplexer includes an antenna terminal, an inductance is disposed between the antennal terminal and an antenna, and the duplexer further includes a capacitor connected between a connection point between the inductance and the antenna and a ground potential.

15. A duplexer, comprising:
a transmission-side band filter including a plurality of surface acoustic wave resonators connected together to define a ladder circuit;
a reception-side band filter including a plurality of surface acoustic wave resonators connected together to define a ladder circuit; wherein
each of the plurality of surface acoustic wave resonators of the transmission-side band filter and the reception-side band filter includes a 47° to 58° rotated, Y-cut, X-propagating LiNbO₃ substrate and an IDT electrode provided on the LiNbO₃ substrate;
the IDT electrode includes a Ti foundation electrode layer disposed on the LiNbO₃ substrate and an Al electrode layer disposed on the Ti foundation electrode layer.

16. The duplexer according to claim 15, wherein a (111) face of the Al electrode layer, one of a (001) face and (100) face of the Ti foundation electrode layer, and a (001) face of the LiNbO₃ substrate are aligned in parallel.

17. The duplexer according to claim 15, where the Ti foundation electrode layer is an epitaxially grown electrode layer on the LiNbO₃ substrate and the Al electrode layer is an epitaxially grown electrode layer on the Ti foundation electrode layer.

18. The duplexer according to claim 15, wherein in the reception-side band filter, a first inductance is disposed in parallel with respect to at least one serial arm resonator connected to a serial arm of the ladder circuit among the plurality of surface acoustic wave resonators, and in the transmission-side band filter, a second inductance is disposed between a parallel arm resonator connected to a parallel arm of the ladder circuit among the plurality of surface acoustic wave resonators and a ground potential.

19. The duplexer according to claim 18, wherein the first inductance and the second inductance are respectively defined by at least one of a wire bonding used for electrical connection in the duplexer, a line embedded in the duplexer, and an external coil component.

20. The duplexer according to claim 18, wherein the first inductance and the second inductance are respectively defined by at least one of a wire bonding used for electrical connection in the duplexer and a line embedded in the duplexer.

21. The duplexer according to claim 15, wherein the transmission-side band filter includes three serial arm resonators and two parallel arm resonators defining the ladder circuit.

22. The duplexer according to claim 15, wherein the reception-side band filter includes three serial arm resonators and two parallel arm resonators defining the ladder circuit.

23. The duplexer according to claim 15, wherein the LiNbO₃ substrate is a 55° rotated, Y-cut, X-propagating LiNbO₃ substrate.

24. A communication device, comprising the duplexer according to claim 15, wherein the duplexer includes an antenna terminal and an antenna, a inductance is disposed between the antennal terminal and the antenna, and the duplexer further includes a capacitor connected between a connection point between the inductance and the antenna and a ground potential.
